(19) United States
(12) Patent Application Publication
(10) Pub. No.: US 2022/0351093 A1
(43) Pub. Date: Nov. 3, 2022

(54) ANALYSIS DEVICE, ANALYSIS METHOD, AND ANALYSIS PROGRAM

(71) Applicant: NIPPON TELEGRAPH AND TELEPHONE CORPORATION, Tokyo (JP)

(72) Inventors: Takayuki ADACHI, Tokyo (JP); Akira NAKAYAMA, Tokyo (JP); Masaru MIYAMOTO, Tokyo (JP)

(73) Assignee: NIPPON TELEGRAPH AND TELEPHONE CORPORATION, Tokyo (JP)

(21) Appl. No.: 17/618,442

(22) PCT Filed: Jun. 12, 2019
(86) PCT No.: PCT/JP2019/023342

§ 371 Date: Dec. 11, 2021

(51) Int. Cl. G06Q 10/04

(52) U.S. Cl. CPC G06Q 10/04

(57) ABSTRACT

It is possible to perform an analysis useful for setting points to be careful in the execution of simulation and understanding movement of people and local situations. A measurement point-to-point information generation unit (130) generates, based on setting data for performing a simulation for a plurality of received measurement points, measurement point-to-point information that is information about between measurement points. A time-series data estimation unit (140) obtains, for each of the plurality of measurement points, based on the measurement point-to-point information and time-series data that is measurement data at the received measurement point in time series, measurement data at the measurement point in time series. A difference analysis unit (150) analyzes information about a difference between the estimated measurement data and the time-series data.

### TECHNICAL FIELD

The present disclosure relates to an analysis device, an analysis method, and an analysis program.

### BACKGROUND ART

In the venues for a large-scale event, many participants may be concentrated around a certain venue, which becomes crowded during the event. Thus, it is important for the people involved in the sponsored event to understand the current situation and take measures before the venue becomes crowded to avoid danger due to the crowding. For example, a large number of people may move between the venue and a station all at once when entering or leaving the venue.

In order to avoid such danger, it is conceivable to carry out simulations in advance to consider measures, predict the occurrence of a situation, and take prepared measures as necessary before the occurrence of danger.

In a simulation carried out in advance, when the event is held regularly or when a similar event is held, the number of people at each measurement point around the venue is measured at that time, and setting for the simulation is made based on the resulting numbers, so that more accurate results can be obtained as simulation results. For example, NPL 1 discloses a technique of targeting a situation where a crowd moves between a venue and a nearby station or the like in a large-scale event, estimating the number of people passing through each movement path in each time zone from the number of passing people locally observed at a fixed point such that an error between the number of passing people and the observed value of the number of passing people is minimized, and reproducing the situation by using a simulation.

### CITATION LIST

### Non Patent Literature

[NPL 1] Hiroshi Kiyotake, Masahiro Kohjima, Tatsushi Matsubayashi, and Hiroyuki Toda, “Estimation of people flow considering time delay”, the 32nd Annual Conference of the Japanese Society for Artificial Intelligence, 2018.

### SUMMARY OF THE INVENTION

### Technical Problem

In the technique of NPL 1, a list (user list) of a start point, a goal point, and waypoints for each participant is created to simulate the movement of the participants; the number of people passing through each movement path and the number of people passing through each measurement point in each time zone are obtained from the result of the simulation; an error between an actual measured value of the number of people passing through the measurement point and the simulation value is calculated; and the number of people passing through each movement path that is likely to make the error smaller is estimated from the relationship between the error and the number of people passing through each movement path. Since the user list can be created from the number of people passing through each movement path, it is possible to obtain the number of people passing through each movement path that approximates the measurement result by repeating a series of steps of processing.

However, a user who uses the technique of NPL 1 is required to define the necessary settings for performing the simulation. For example, a road where the walking speed is uniformly slowed down at a certain time and the like is to be set based on experience, observation of past events, analysis of measurement data. Therefore, there is a problem that it is difficult for a user who is not familiar with the movement of people and the local situation to set such settings.

The technique disclosed herein has been made in view of the foregoing, and an object of the disclosure is to provide an analysis device, an analysis method, and an analysis program that are capable of performing an analysis useful for setting points to be careful in the execution of simulation and understanding movement of people and local situations.

### Means for Solving the Problem

A first aspect of the present disclosure is an analysis device including: a setting data input unit that receives input of setting data for performing a simulation for a plurality of measurement points; a time-series data input unit that receives, for each of the plurality of measurement points, input of time-series data that is measurement data at the measurement point in time series; a measurement point-to-point information generation unit that generates, based on the setting data, measurement point-to-point information that is information about between the measurement points; a time-series data estimation unit that estimates, for each of the plurality of measurement points, based on the measurement point-to-point information and the time-series data, measurement data at the measurement point in time series; and a difference analysis unit that analyzes, for each of the plurality of measurement points, information about a difference between the time-series data at the measurement point and estimated data that is the measurement data estimated for the measurement point by the time-series data estimation unit.

A second aspect of the present disclosure is an analysis method including: receiving, by a setting data input unit, input of setting data for performing a simulation for a plurality of measurement points; receiving, by a time-series data input unit, for each of the plurality of measurement points, input of time-series data that is measurement data at the measurement point in time series; generating, by a measurement point-to-point information generation unit, based on the setting data, measurement point-to-point information that is information about between the measurement points; estimating, by a time-series data estimation unit, for each of the plurality of measurement points, based on the measurement point-to-point information and the time-series data, measurement data at the measurement point in time series; and analyzing, by a difference analysis unit, for each of the plurality of measurement points, information about a difference between the time-series data at the measurement point and estimated data that is the measurement data estimated for the measurement point by the time-series data estimation unit.

A third aspect of the present disclosure is an analysis program causing a computer to execute: receiving, by a setting data input unit, input of setting data for performing a simulation for a plurality of measurement points; receiving, by a time-series data input unit, for each of the plurality of measurement points, input of time-series data that is measurement data at the measurement point in time series; generating, by a measurement point-to-point information generation unit, based on the setting data, measurement point-to-point information that is information about between the measurement points; estimating, by a time-series data estimation unit, for each of the plurality of measurement points, based on the measurement point-to-point information and the time-series data, measurement data at the measurement point in time series; and analyzing, by a difference analysis unit, for each of the plurality of measurement points, information about a difference between the time-series data at the measurement point and estimated data that is the measurement data estimated for the measurement point by the time-series data estimation unit.

### Effects of the Invention

According to the technique disclosed herein, it is possible to perform an analysis useful for setting points to be careful in the execution of simulation and understanding movement of people and local situations.

### BRIEF DESCRIPTION OF DRAWINGS

FIG. 1 is a block diagram illustrating a schematic configuration of a computer that functions as an analysis device according to an embodiment.

FIG. 2 is a block diagram illustrating an example of a functional configuration of the analysis device according to the embodiment.

FIG. 3 is a diagram illustrating a relationship between an adjacent upstream measurement point and a downstream measurement point.

FIG. 4 is a diagram illustrating a configuration example of measurement points according to Example 1 of a difference analysis.

FIG. 5 is a graph representing time-series data at a measurement point A according to Example 1 of the difference analysis.

FIG. 6 is a graph representing time-series data at a measurement point B according to Example 1 of the difference analysis.

FIG. 7 is a graph representing a data difference between time-series data and estimated data at a downstream measurement point C according to Example 1 of the difference analysis.

FIG. 8 is a graph representing a cumulative difference between time-series data and estimated data at the downstream measurement point C according to Example 1 of the difference analysis.

FIG. 9 is a flowchart illustrating an analysis processing routine of the analysis device according to the present embodiment.

FIG. 10 is a flowchart illustrating a data estimation processing routine of the analysis device according to the present embodiment.

FIG. 11 is a diagram illustrating relationships among start points and downstream measurement points.

### DESCRIPTION OF EMBODIMENTS

<Configuration of Analysis Device According to Embodiment of Present Disclosed Technique>

Embodiment examples of the disclosed technique will be described below with reference to the drawings. Note that the same reference numerals are given to the same or equivalent components and parts throughout the drawings. Further, the dimensional ratios in the drawings are exaggerated for convenience of explanation and may differ from the actual ratios.

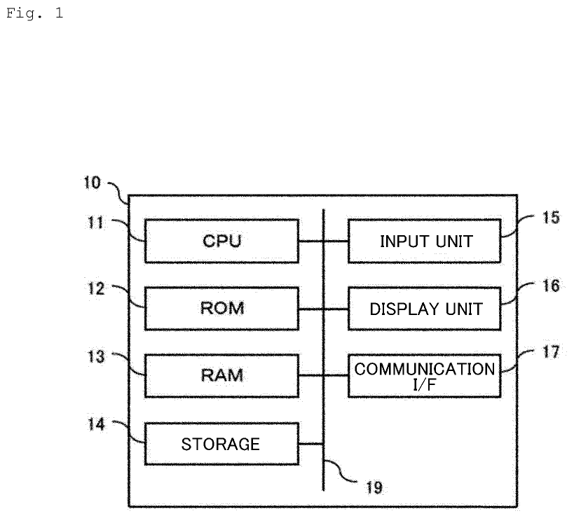

FIG. 1 is a block diagram illustrating a hardware configuration of an analysis device 10 according to the present embodiment. As illustrated in FIG. 1, the analysis device 10 includes a CPU (Central Processing Unit) 11, a ROM (Read Only Memory) 12, a RAM (Random Access Memory) 13, a storage 14, an input unit 15, a display unit 16, and a communication interface (I/F) 17. The respective components are communicably connected to each other via a bus 19.

The CPU 11, which is a central arithmetic processing unit, executes various types of programs and controls each component. Specifically, the CPU 11 reads a program from the ROM 12 or the storage 14, and executes the program using the RAM 13 as a work area. The CPU 11 controls each of the above-mentioned components and performs various types of arithmetic processing in accordance with the program stored in the ROM 12 or the storage 14. In the present embodiment, the ROM 12 or the storage 14 stores an analysis program for executing analysis processing.

The ROM 12 stores various types of programs and various types of data. The RAM 13 serves as a work area to temporarily store programs or data. The storage 14 is composed of an HDD (Hard Disk Drive) or SSD (Solid State Drive) to store various types of programs including an operating system, and various types of data.

The input unit 15 includes a pointing device such as a mouse and a keyboard, and is used for performing various types of inputs.

The display unit 16 is, for example, a liquid crystal display and displays various types of information. The display unit 16 may adopt a touch panel type to function as the input unit 15.

The communication interface 17 is an interface for communicating with other devices, and uses, for example, standards such as Ethernet (registered trademark), FDDI, and Wi-Fi (registered trademark).

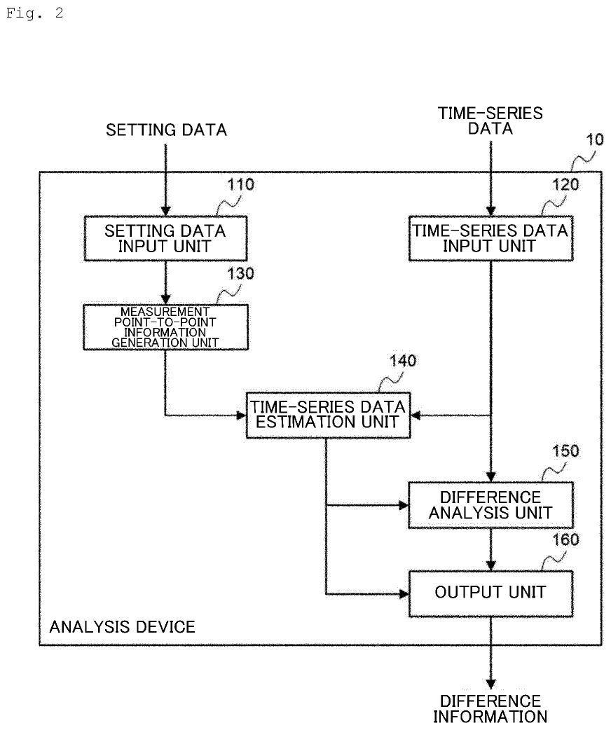

Next, a functional configuration of the analysis device 10 will be described. FIG. 2 is a block diagram illustrating an example of the functional configuration of the analysis device 10.

As illustrated in FIG. 2, the analysis device 10 includes a setting data input unit 110, a time-series data input unit 120, a measurement point-to-point information generation unit 130, a time-series data estimation unit 140, a difference analysis unit 150, and an output unit 160, which serve as functional components. Each functional component is realized by the CPU 11 reading the analysis program stored in the ROM 12 or the storage 14, loading the analysis program into the RAM 13, and executing the analysis program.

The setting data input unit 110 receives input of setting data for performing a simulation for a plurality of measurement points. The setting data includes a directed graph in which each of the plurality of measurement points is defined as a node and each path between the measurement points is defined as an edge. For example, when a target to be simulated is a flow of people in a large-scale event including a road network composed of a plurality of roads, the directed graph is expressed with an end point of each road as a node and with each road as an edge. In the directed graph, the direction of the road is also taken into consideration. Hereinafter, a case where the directed graph represents a road network will be described as an example.

Further, the setting data includes information on the measurement points. The information on the measurement points is, for example, of the nodes, a list of nodes that are the measurement points. Note that the measurement point is always a node. Further, the information on the measurement points includes information on what kind of measurement data are to be measured at the measurement point. In the following, a case will be described by way of example in which the measurement data to be measured at the measurement point is the number of people passing through the measurement point. Even for the same edge, if both the immediately preceding node and the immediately following node are specified, the number of passing people in a different direction is represented.

Further, the setting data includes information on movement speed information. For example, as the movement speed information, the average value of the movement speed and the normal distribution can be assumed, and the mean and standard deviation can be adopted. Further, a coefficient for changing the movement speed may be given for each road.

Then, the setting data input unit 110 passes the received setting data to the measurement point-to-point information generation unit 130.

The time-series data input unit 120 receives, for each of the plurality of measurement points, input of measurement data at the measurement point in time series. Specifically, the time-series data input unit 120 receives, for each of the plurality of measurement points, input of, as the time-series data, time-series data of the number of passing people in which the numbers of people passing through the measurement point at the respective times are arranged in order of time. Then, the time-series data input unit 120 passes the received time-series data to the time-series data estimation unit 140 and the difference analysis unit 150.

The measurement point-to-point information generation unit 130 generates, based on the setting data, measurement point-to-point information that is information about between the measurement points. Specifically, the measurement point-to-point information generation unit 130 sets, for each of the plurality of measurement points, as an upstream measurement point, a measurement point that is adjacent to that measurement point and also heads toward that measurement point.

The measurement point-to-point information generation unit 130 obtains, for each of the plurality of measurement points, a measurement point adjacent to that measurement point from the directed graph and the information on the measurement point which are included in the setting data, and sets, as an upstream measurement point, the measurement point that is the obtained measurement point adjacent to that measurement point and also heads toward that measurement point. Next, the measurement point-to-point information generation unit 130 sets, as a downstream measurement point, the measurement point associated with the upstream measurement point, and generates a pair of the upstream measurement point and the downstream measurement point. Further, the measurement point-to-point information generation unit 130 calculates, based on the distance between the upstream measurement point and the downstream measurement point and the movement speed information included in the setting data, a moving time from the upstream measurement point to the downstream measurement point. Here, the distance between the measurement points is the distance of the shortest path, and passage nodes on the path are recorded in advance. Note that instead of the shortest path, a path whose ease of passage (e.g., a relationship between the width and length of a road) is given priority may be used as a path between the measurement points. Further, a path of adjacent measurement points is added to the setting data in advance, and that path in the setting data may be used as a path between the measurement points. Then, the measurement point-to-point information generation unit 130 passes each of the generated pairs of upstream measurement point and downstream measurement point and a moving time between the paired points to the difference analysis unit 150 and the output unit 160.

The time-series data estimation unit 140 estimates, for each of the plurality of measurement points, time-series measurement data at the measurement point based on the measurement point-to-point information and the time-series data. Specifically, the time-series data estimation unit 140 first obtains upstream measurement points adjacent to each of the downstream measurement points based on the measurement point-to-point information. Next, the time-series data estimation unit 140 learns, for each of the downstream measurement points, based on the time-series data at each of the upstream measurement points adjacent to the downstream measurement point and the time-series data at the downstream measurement point, a weight coefficient of a linear regression equation in which an objective variable is the time-series data at the downstream measurement point, an explanatory variable is the time-series data at each of the upstream measurement points adjacent to the downstream measurement point, and the weight coefficient is for a relationship between the downstream measurement point and each of the upstream measurement points adjacent to the downstream measurement point. Next, the time-series data estimation unit 140 estimates, from the time-series data at each of the upstream measurement points, based on the linear regression equation using the learned weight coefficient, time-series data at the corresponding downstream measurement point. The above processing will be described below in detail.

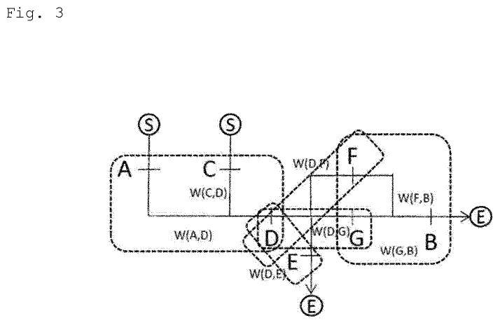

FIG. 3 is a diagram illustrating a relationship between an adjacent upstream measurement points and a downstream measurement point. In FIG. 3, S in a circle is a start point, E in a circle is a goal point, and A to F are measurement points. In this case, each of the measurement point A and the measurement point C does not have an upstream measurement point because there is no measurement point on their upstream start point S side. On the other hand, each of the measurement point B and the measurement points D to G has an adjacent upstream measurement point or adjacent upstream measurement points on the start point S side (a range surrounded by a broken line in FIG. 3). The time-series data estimation unit 140 learns weight coefficient(s) w for each of the five downstream measurement points of the downstream measurement point B and the downstream measurement points D to G based on the following five types of linear regression equations (the following Equations (1) to (5)).

y(B)=w(F,B)×x(F)+w(G,B)×x(G)+b(B) (1)

y(D)=w(A,D)×x(A)+w(C,D)×x(C)+b(D) (2)

y(E)=w(D,E)×x(D)+b(E) (3)

y(F)=w(D,F)×x(D)+b(F) (4)

y(G)=w(D,G)×x(D)+b(G) (5)

Here, in the above linear regression equations, time-series data y(Q) is an objective variable for downstream measurement point Q, time-series data x(P) is an explanatory variable for upstream measurement point P, and b(Q) is a value related to downstream measurement point Q not depending on upstream measurement point P.

Now focusing on the downstream measurement point D, the time-series data estimation unit 140 obtains, from the pieces of time-series data, the time-series data at the upstream measurement point A and time-series data at the upstream measurement point C, which correspond to the respective times in the time-series data at the downstream measurement point D. More specifically, the time-series data estimation unit 140 extracts, for the upstream measurement point A that affects the downstream measurement point D, from the pieces of time-series data, a moving time from the upstream measurement point A to the downstream measurement point D, and time-series data x(A) at the upstream measurement point A at past times corresponding to the respective times in the time-series data at the downstream measurement point D. Similarly, the time-series data estimation unit 140 extracts, for the upstream measurement point C that affects the downstream measurement point D, from the pieces of time-series data, a moving time from the upstream measurement point C to the downstream measurement point D, and time-series data x(C) at the upstream measurement point C at past times corresponding to the respective times in the time-series data at the downstream measurement point D.

Next, the time-series data estimation unit 140 learns weight coefficient w(A, D), weight coefficient w(C, D), and b(D) of the linear regression equation for the downstream measurement point D represented by Equation (2), based on measurement data y(D) at the downstream measurement point D, and time-series data x(A) and time-series data x(C) which correspond to the respective times in the time-series data at the downstream measurement point D.

Next, by using Equation (2) with time-series data x(A) and time-series data x(C) which correspond to the respective times in the time-series data at the downstream measurement point D, and the learned weight coefficient w(A, D), weight coefficient w(C, D), and b(D), the time-series data estimation unit 140 estimates time-series data at the downstream measurement point D at the respective times. Hereinafter, the estimated time-series data at the downstream measurement point D will be referred to as the estimated data at the downstream measurement point D. For the other downstream measurement points, the time-series data estimation unit 140 also obtains the estimated data at each downstream measurement point as in the case of the downstream measurement point D.

Then, the time-series data estimation unit 140 passes the estimated data for each of the downstream measurement points to the difference analysis unit 150. Further, the time-series data estimation unit 140 passes correlation coefficients calculated by the calculation of the linear regression equations to the difference analysis unit 150.

The difference analysis unit 150 obtains, for each of the downstream measurement points, a difference between the time-series data at the downstream measurement point and the estimated data at the downstream measurement point, and analyzes the information related to the difference. Specifically, first, the difference analysis unit 150 obtains, for each of the downstream measurement points, a data difference that is a difference between the time-series data at the downstream measurement point and the estimated data at the downstream measurement point. Further, the difference analysis unit 150 obtains, for each of the downstream measurement points, a cumulative difference that is a difference between measurement data in which pieces of time-series data at the respective upstream measurement points adjacent to the downstream measurement point are accumulated over time and measurement data in which pieces of time-series data at the downstream measurement point are accumulated over time. Next, the difference analysis unit 150 determines a factor that causes the data difference and the cumulative difference for each of the downstream measurement points. Hereinafter, processing of the difference analysis unit 150 will be described by way of example of the following difference analysis. Note that in the example of the difference analysis below, various types of data indicate the number of people passing through the measurement point.

<<Example of Difference Analysis>>

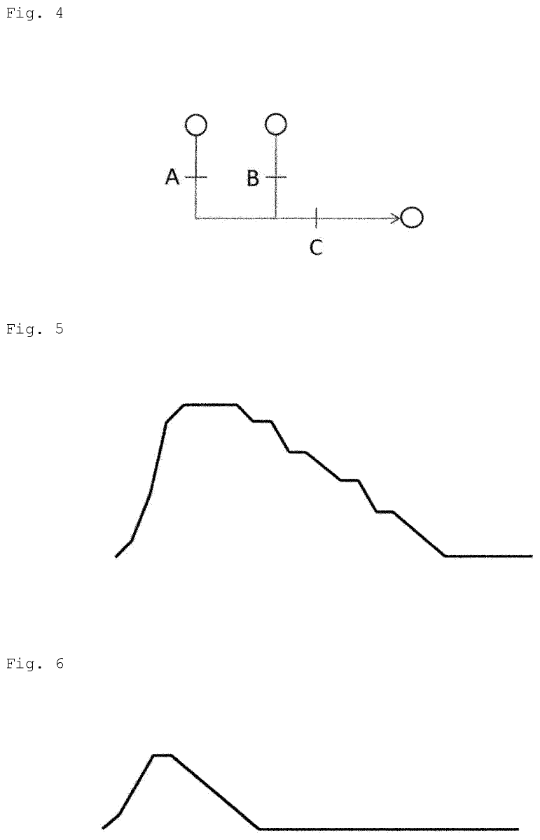

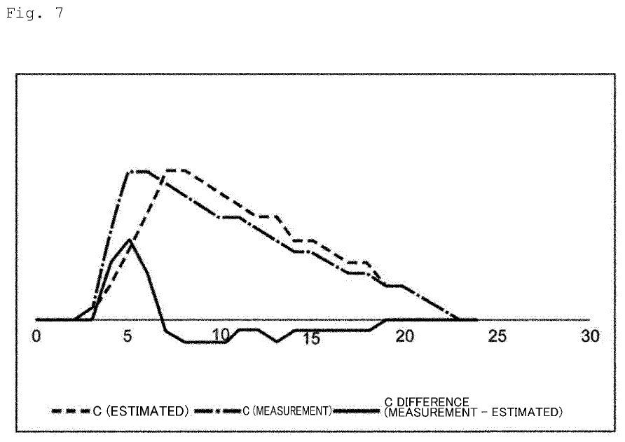

FIG. 4 is a diagram illustrating a configuration example of measurement points according to an example of the difference analysis. In the example of the difference analysis, the measurement point C is a downstream measurement point, and a measurement point A and a measurement point B are upstream measurement points for a downstream measurement point C. FIG. 5 is a graph representing time-series data at the measurement point A according to an example of the difference analysis. FIG. 6 is a graph representing time-series data at the measurement point B according to an example of the difference analysis. In the example of the difference analysis, it is assumed that the time-series data estimation unit 140 has obtained estimated data in which time-series data at the downstream measurement points C is estimated by using the time-series data at the upstream measurement point A and the upstream measurement point B illustrated in FIGS. 5 and 6 in the case of movement through the distance from the upstream measurement point A to the downstream measurement point C and the distance from the upstream measurement point B to the downstream measurement point C at a constant walking speed.

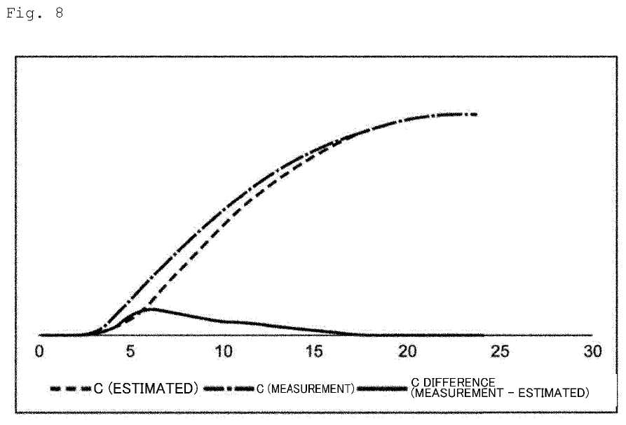

FIG. 7 is a graph representing a data difference between time-series data and estimated data at the downstream measurement point C according to an example of the difference analysis. In FIG. 7, the horizontal axis represents the time series, the broken line represents the estimated data at the downstream measurement point C, and the chain line represents the time-series data at the downstream measurement point C. The difference analysis unit 150 obtains a data difference represented by the solid line in FIG. 7, which is a difference between the estimated data and the time-series data. Here, a value obtained by subtracting estimated data from measurement data is used as the data difference.

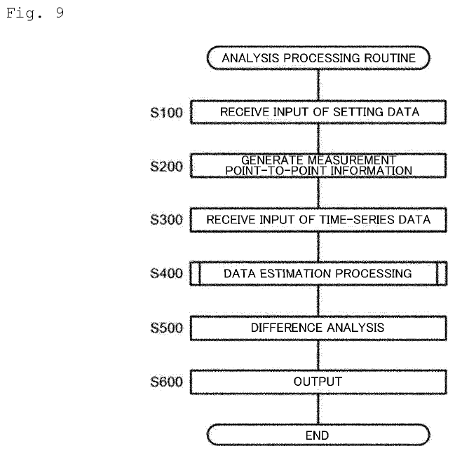

Further, FIG. 8 is a graph representing a cumulative difference between time-series data and estimated data at the downstream measurement point C according to an example of the difference analysis. In FIG. 8, the horizontal axis represents the time series, the broken line represents the measurement data in which pieces of estimated data at the downstream measurement point C are accumulated over time, and the chain line represents the measurement data in which pieces of time-series data at the downstream measurement point C are accumulated over time. The difference analysis unit 150 obtains the cumulative difference represented by the solid line in FIG. 8, which is a difference between the measurement data in which the pieces of estimated data are accumulated and the measurement data in which the pieces of time-series data are accumulated. Here, a value obtained by subtracting the accumulated pieces of estimated data from the accumulated pieces of measurement data is used as the cumulative difference. Then, the difference analysis unit 150 obtains an analysis result according to a predetermined rule based on the time at which the data difference is large, the time at which the data difference is small, and the time at which the cumulative difference occurs.

In FIG. 7, the measurement data (the number of passing people) is larger than the estimated data at time t=4 to 6, and the measurement data (the number of passing people) is smaller than the estimated data at time t=7 to 18. Further, it can be seen from FIG. 8 that a positive cumulative difference occurs at time t=4 to 17, that is, people arrive earlier than a reference that a person who has passed through the upstream measurement point A or the upstream measurement point B travels at a predetermined walking speed (constant) and arrives at the downstream measurement point C. Therefore, the difference analysis unit 150 can create a document that it is estimated that people will arrive at the downstream measurement point C from the upstream measurement point A or the upstream measurement point B in the time zone of time t=4 to 17 as early as the measurement data, as compared with other time zones, and can use the document as an analysis result. Further, the difference analysis unit 150 can calculate a coefficient for the walking speed of a person walking on roads from the measurement point A to the measurement point C and from the measurement point B to the measurement point C in this time zone such that the coefficient is larger than the coefficient for the constant speed used for estimation, and can use the calculated coefficient as an analysis result. Further, as one of the setting condition files used in other simulations, a setting file for setting the coefficient for the walking speed on a road to be larger than usual at a certain time can be used as an analysis result. For example, when the walking speed coefficient for a road from the measurement point A to the measurement point C and a road from the measurement point B to the measurement point C is set to 2.0 at time t=4 to 17, a setting file in which, for example, “4, 17, A, C, 2.0” and “4, 17, B, C, 2.0” are described is used. Note that the coefficient for changing the walking speed can be obtained, for example, by “the number of people at C (measurement)/the number of people at C (estimated)” in the section where the C difference in FIG. 7 is positive, but any method may be used as long as the same result is obtained.

In this way, the difference analysis unit 150 derives analysis results that can be read based on the data differences, the cumulative differences, the averages, the variances, and the correlation coefficients. Then, the difference analysis unit 150 passes, to the output unit 160, the time-series data at the downstream measurement points, the analysis results, and a factor statement which is data documenting the factors included in the analysis results. Further, when the correlation coefficient(s) is/are low, the difference analysis unit 150 also passes that fact to the output unit 160.

For each of the downstream measurement points received from the difference analysis unit 150, the output unit 160 outputs the time-series data at the downstream measurement points, the analysis results, and information about the factor statement which is data documenting the factors included in the analysis results and about the correlation coefficients. For example, a document to be output describes “In FIG. 7, the measurement data (the number of passing people) is larger than the estimated data at time t=4 to 6, and the measurement data (the number of passing people) is smaller than the estimated data at time t=7 to 18. Further, in FIG. 8, a positive cumulative difference occurs at time t=4 to 17. It is considered that people arrive earlier than a reference that a person who has passed through the upstream measurement point travels at a constant walking speed and arrives at the downstream measurement point.” Further, the output unit 160 may also output a graph (e.g., FIG. 7) capable of visually grasping the difference, or may output only that graph. Further, a setting file for reflecting this result in a simulator to be used separately may be output.

<Operation of Analysis Device According to Embodiment of Present Disclosed Technique>

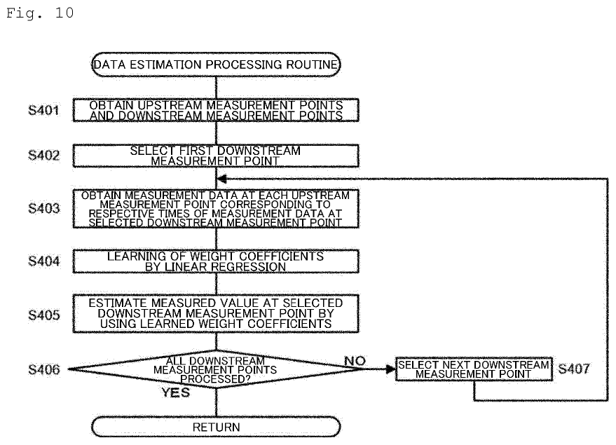

Next, an operation of the analysis device 10 will be described. FIG. 9 is a flowchart illustrating a flow of an analysis processing routine performed by the analysis device 10. The analysis processing routine is performed by the CPU 11 reading the analysis program from the ROM 12 or the storage 14, loading the analysis program into the RAM 13, and executing the analysis program.

In step S100, the CPU 11 serves as the setting data input unit 110 to receive input of setting data for performing a simulation for a plurality of measurement points.

In step S200, the CPU 11 serves as the measurement point-to-point information generation unit 130 to generate, based on the setting data received in step S100, measurement point-to-point information that is information about between the measurement points.

In step S300, the CPU 11 serves as the time-series data input unit 120 to receive, for each of the plurality of measurement points, input of measurement data at the measurement point in time series.

In step S400, the CPU 11 serves as the time-series data estimation unit 140 to estimate, for each of the plurality of measurement points, time-series measurement data at the measurement point based on the measurement point-to-point information and the time-series data.

In step S500, the CPU 11 serves as the difference analysis unit 150 to obtain, for each of the downstream measurement points, a difference between the time-series data at the downstream measurement point and the estimated data at the downstream measurement point, and analyzes the factor that causes the difference.

In step S600, the CPU 11 serves as the output unit 160 to output the analysis results, and ends the processing.

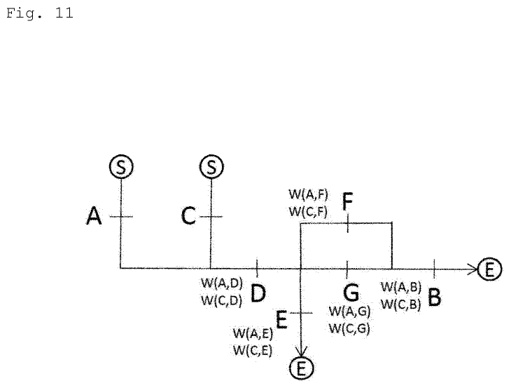

Here, the data estimation processing in step S400 will be described in detail. FIG. 10 is a flowchart illustrating a flow of a data estimation processing routine performed by the analysis device 10.

In step S401, the CPU 11 serves as the time-series data estimation unit 140 to obtain upstream measurement points and downstream measurement points.

In step S402, the CPU 11 serves as the time-series data estimation unit 140 to select the first downstream measurement point. Hereinafter, the downstream measurement point selected in this step is referred to as the “selected downstream measurement point”.

In step S403, the CPU 11 serves as the time-series data estimation unit 140 to obtain time-series data at each of the upstream measurement points adjacent to the selected downstream measurement point from among the pieces of time-series data received in step S300.

In step S404, the CPU 11 serves as the time-series data estimation unit 140 to learn, based on the time-series data at each of the upstream measurement points adjacent to the selected downstream measurement point and the time-series data at the selected downstream measurement point, a weight coefficient of a linear regression equation in which an objective variable is the time-series data at the selected downstream measurement point, an explanatory variable is the time-series data at each of the upstream measurement points adjacent to the selected downstream measurement point, and the weight coefficient is for a relationship between the selected downstream measurement point and each of the upstream measurement points adjacent to the selected downstream measurement point.

In step S405, the CPU 11 serves as the time-series data estimation unit 140 to estimate, from the time-series data at each of the upstream measurement points, based on the linear regression equation using the weight coefficient learned in step S405, time-series data at the corresponding downstream measurement point.

In step S406, the CPU 11 serves as the time-series data estimation unit 140 to determine whether or not the processing has been performed on all the downstream measurement points.

If the processing has not been performed on all the downstream measurement points (NO in step S406), in step S407, the CPU 11 serves as the time-series data estimation unit 140 to select the next downstream measurement point, and then returns to step S403. On the other hand, if the processing has been performed on all the downstream measurement points (YES in step S406), the processing returns.

As described above, the analysis device according to the embodiment of the present disclosure generates measurement point-to-point information, which is information about between measurement points, based on setting data for performing a simulation at a plurality of received measurement points. The analysis device according to the embodiment of the present disclosure estimates, for each of the plurality of measurement points, based on the measurement point-to-point information and time-series data that is measurement data at the received measurement point in time series, measurement data at the measurement point in time series. Then, the analysis device according to the embodiment of the present disclosure analyzes information about a difference between the estimated measurement data and the time-series data. As a result, it is possible to estimate measurement data at a certain measurement point from a relationship of measurement data between the measurement points, and present a difference between the actual measurement data and the estimated measurement data as a reference. Therefore, it is possible to perform an analysis useful for setting points to be careful in the execution of simulation and understanding movement of people and local situations.

Note that the present disclosure is not limited to the above-described embodiment, and various modifications and applications are possible without departing from the scope and spirit of the present invention.

For example, in the above-described embodiment, the relationship between the downstream measurement point and the upstream measurement point adjacent to the downstream measurement point is used, but the present invention is not limited to this, and a configuration may be adopted in which a relationship between the downstream measurement point and an upstream measurement point that is not adjacent to the downstream measurement point is used.

In this case, the time-series data estimation unit 140 can select an upstream measurement point to be used based on a path ratio. For example, in the configuration of FIG. 3, the relationships among each of the five downstream measurement points of the downstream measurement point B and the downstream measurement points D to G and the upstream measurement point A and the upstream measurement point C which are closer to the start points S can be used based on their path ratios. FIG. 11 is a diagram illustrating relationships among start points and downstream measurement points. In this case, the time-series data estimation unit 140 can learn weight coefficient (s) w for each of the five downstream measurement points based on the following five types of linear regression equations (the following Equations (6) to (10)).

Y(B)=w(A,B)×x(A)+w(C,B)×x(C)+b(B) (6)

Y(D)=w(A,D)×x(A)+w(C,D)×x(C)+b(D) (7)

Y(E)=w(A,E)×x(A)+w(C,E)×x(C)+b(E) (8)

Y(F)=w(A,F)×x(A)+w(C,F)×x(C)+b(F) (9)

Y(G)=w(A,G)×x(A)+w(C,G)×x(C)+b(G) (10)

Further, instead of the time-series data at the adjacent upstream measurement points in the above embodiment, time-series data at the downstream measurement point can be estimated by using the time-series data at the upstream measurement point A and the time-series data at the upstream measurement point C.

Further, in the above-described embodiment, the analysis device 10 is configured as one device, but the respective steps of processing may be deployed to separate devices and the analysis processing may be performed via a network.

Note that in the above embodiment, various types of processors other than the CPU may execute the analysis program executed by the CPU reading the software (program). Examples of the processors in this case include PLD (Programmable Logic Device) whose circuitry is reconfigurable after manufacturing, such as FPGA (Field-Programmable Gate Array), a dedicated electric circuit, which is a processor having circuitry specially designed for performing specific processing, such as ASIC (Application Specific Integrated Circuit), and the like. Further, the analysis program may be executed by one of these various types of processors, or a combination of two or more processors of the same type or different types (e.g., a plurality of FPGAs and a combination of a CPU and an FPGA, etc.). Further, the hardware configuration of these various types of processors is, more specifically, an electric circuit in which circuit elements such as semiconductor elements are combined.

Further, in the above embodiment, an aspect has been described in which the analysis program is previously stored (installed) in the ROM 12 or the storage 14. However, the present invention is not limited to this. The program may be provided in the form of being stored in a non-transitory storage medium such as CD-ROM (Compact Disk Read Only Memory), DVD-ROM (Digital Versatile Disk Read Only Memory), and USB (Universal Serial Bus). Further, the program may be in the form of being downloaded from an external device via a network.

The following Notes will be further disclosed with respect to the above embodiment.

Note 1

An analysis device including:

a memory; and

at least one processor connected to the memory, wherein

the processor is configured to:
receive input of setting data for performing a simulation for a plurality of measurement points;
receive, for each of the plurality of measurement points, input of time-series data that is measurement data at the measurement point in time series;
generate, based on the setting data, measurement point-to-point information that is information about between the measurement points;
estimate, for each of the plurality of measurement points, based on the measurement point-to-point information and the time-series data, measurement data at the measurement point in time series; and
analyze, for each of the plurality of measurement points, information about a difference between the time-series data at the measurement point and estimated data that is the measurement data estimated for the measurement point by the time-series data estimation unit.

Note 2

A non-transitory storage medium storing an analysis program that causes a computer to execute:

receiving input of setting data for performing a simulation for a plurality of measurement points;

receiving, for each of the plurality of measurement points, input of time-series data that is measurement data at the measurement point in time series;

generating, based on the setting data, measurement point-to-point information that is information about between the measurement points;

estimating, for each of the plurality of measurement points, based on the measurement point-to-point information and the time-series data, measurement data at the measurement point in time series; and

analyzing, for each of the plurality of measurement points, information about a difference between the time-series data at the measurement point and estimated data that is the measurement data estimated for the measurement point by the time-series data estimation unit.

### REFERENCE SIGNS LIST

10 Analysis device
11 CPU
12 ROM
13 RAM
14 Storage
15 Input unit
16 Display unit
17 Communication Interface
19 Bus
110 Setting data input unit
120 Time-series data input unit
130 Measurement point-to-point information generation unit
140 Time-series data estimation unit
150 Difference analysis unit
160 Output unit

1. An analysis device comprising circuitry configured to execute a method comprising:
receiving input of setting data for performing a simulation for a plurality of measurement points;
receiving, for each of the plurality of measurement points, input of time-series data that is measurement data at the measurement point in time series;
generating, based on the setting data, measurement point-to-point information that is information about between the measurement points;
estimating, for each of the plurality of measurement points, based on the measurement point-to-point information and the time-series data, measurement data at the measurement point in time series; and
analyzing, for each of the plurality of measurement points, information about a difference between the time-series data at the measurement point and estimated data that is the measurement data estimated for the measurement point.

2. The analysis device according to claim 1, wherein
the setting data includes a directed graph in which each of the plurality of points is defined as a node and each path between the measurement points is defined as an edge, and the circuitry configured to execute the method further comprising:
setting, for each of the plurality of measurement points, as an upstream measurement point, a measurement point that is adjacent to that measurement point and is adjacent on upstream side;
estimating, for each of downstream measurement points that are measurement points associated with the upstream measurement point among the plurality of measurement points, based on the time-series data at each upstream measurement point for the downstream measurement point, the estimated data at the downstream measurement point; and
analyzing, for each of the downstream measurement points, a factor that causes a difference between the time-series data at the downstream measurement point and the estimated data at the downstream measurement point.

3. The analysis device according to claim 2, the circuitry further configured to execute the method comprising:
outputting, as an analysis result, at least one of an explanatory text of the factor, a graph capable of visually grasping the difference, and setting data used for a simulation for measurement data at each measurement point.

4. The analysis device according to claim 1, the circuitry further configured to execute the method comprising:
learning, for each of downstream measurement points, based on the time-series data at each of upstream measurement points adjacent to the downstream measurement point and the time-series data at the downstream measurement point, a weight coefficient of a linear regression equation in which an objective variable is the time-series data at the downstream measurement point, an explanatory variable is the time-series data at each of upstream measurement points adjacent to the downstream measurement point, and the weight coefficient is for a relationship between the downstream measurement point and each of the upstream measurement points adjacent to the downstream measurement point; and
estimating, from the time-series data at each of the upstream measurement points adjacent to the downstream measurement point, based on the linear regression equation using the learned weight coefficient, time-series data at the downstream measurement point.

5. An analysis method comprising:
receiving input of setting data for performing a simulation for a plurality of measurement points;
receiving, for each of the plurality of measurement points, input of time-series data that is measurement data at the measurement point in time series;
generating, based on the setting data, measurement point-to-point information that is information about between the measurement points;
estimating, for each of the plurality of measurement points, based on the measurement point-to-point information and the time-series data, measurement data at the measurement point in time series; and
analyzing, for each of the plurality of measurement points, information about a difference between the time-series data at the measurement point and estimated data that is the measurement data estimated for the measurement point.

6. A computer-readable non-transitory recording medium storing computer-executable analysis program instructions that when executed by a processor cause computer system to execute a method comprising:
receiving, by a setting data input unit, input of setting data for performing a simulation for a plurality of measurement points;
receiving, for each of the plurality of measurement points, input of time-series data that is measurement data at the measurement point in time series;
generating, based on the setting data, measurement point-to-point information that is information about between the measurement points;
estimating, for each of the plurality of measurement points, based on the measurement point-to-point information and the time-series data, measurement data at the measurement point in time series; and
analyzing, for each of the plurality of measurement points, information about a difference between the time-series data at the measurement point and estimated data that is the measurement data estimated for the measurement point.

7. The analysis device according to claim 1, wherein the setting data includes movement speed information.

8. The analysis device according to claim 2, the circuitry configured to execute the method further comprising:
learning, for each of downstream measurement points, based on the time-series data at each of upstream measurement points adjacent to the downstream measurement point and the time-series data at the downstream measurement point, a weight coefficient of a linear regression equation in which an objective variable is the time-series data at the downstream measurement point, an explanatory variable is the time-series data at each of upstream measurement points adjacent to the downstream measurement point, and the weight coefficient is for a relationship between the downstream measurement point and each of the upstream measurement points adjacent to the downstream measurement point; and
estimating, from the time-series data at each of the upstream measurement points adjacent to the downstream measurement point, based on the linear regression equation using the learned weight coefficient, time-series data at the downstream measurement point.

9. The analysis device according to claim 3, the circuitry configured to execute the method further comprising:
learning, for each of downstream measurement points, based on the time-series data at each of upstream measurement points adjacent to the downstream measurement point and the time-series data at the downstream measurement point, a weight coefficient of a linear regression equation in which an objective variable is the time-series data at the downstream measurement point, an explanatory variable is the time-series data at each of upstream measurement points adjacent to the downstream measurement point, and the weight coefficient is for a relationship between the downstream measurement point and each of the upstream measurement points adjacent to the downstream measurement point; and
estimating, from the time-series data at each of the upstream measurement points adjacent to the downstream measurement point, based on the linear regression equation using the learned weight coefficient, time-series data at the downstream measurement point.

10. The analysis method according to claim 5, wherein the setting data includes a directed graph in which each of the plurality of points is defined as a node and each path between the measurement points is defined as an edge, and the method further comprising:
setting, for each of the plurality of measurement points, as an upstream measurement point, a measurement point that is adjacent to that measurement point and is adjacent on upstream side;
estimating, for each of downstream measurement points that are measurement points associated with the upstream measurement point among the plurality of measurement points, based on the time-series data at each upstream measurement point for the downstream measurement point, the estimated data at the downstream measurement point; and
analyzing, for each of the downstream measurement points, a factor that causes a difference between the time-series data at the downstream measurement point and the estimated data at the downstream measurement point.

11. The analysis method according to claim 5, the method further comprising:
learning, for each of downstream measurement points, based on the time-series data at each of upstream measurement points adjacent to the downstream measurement point and the time-series data at the downstream measurement point, a weight coefficient of a linear regression equation in which an objective variable is the time-series data at the downstream measurement point, an explanatory variable is the time-series data at each of upstream measurement points adjacent to the downstream measurement point, and the weight coefficient is for a relationship between the downstream measurement point and each of the upstream measurement points adjacent to the downstream measurement point; and
estimating, from the time-series data at each of the upstream measurement points adjacent to the downstream measurement point, based on the linear regression equation using the learned weight coefficient, time-series data at the downstream measurement point.

12. The analysis method according to claim 5, wherein the setting data includes movement speed information.

13. The computer-readable non-transitory recording medium according to claim 6, wherein the setting data includes a directed graph in which each of the plurality of points is defined as a node and each path between the measurement points is defined as an edge, and the computer-executable program instructions when executed further causing the computer system to execute the method comprising:
setting, for each of the plurality of measurement points, as an upstream measurement point, a measurement point that is adjacent to that measurement point and is adjacent on upstream side;
estimating, for each of downstream measurement points that are measurement points associated with the upstream measurement point among the plurality of measurement points, based on the time-series data at each upstream measurement point for the downstream measurement point, the estimated data at the downstream measurement point; and
analyzing, for each of the downstream measurement points, a factor that causes a difference between the time-series data at the downstream measurement point and the estimated data at the downstream measurement point.

14. The computer-readable non-transitory recording medium according to claim 6, wherein the setting data includes a directed graph in which each of the plurality of points is defined as a node and each path between the measurement points is defined as an edge, and the computer-executable program instructions when executed further causing the computer system to execute the method comprising:
learning, for each of downstream measurement points, based on the time-series data at each of upstream measurement points adjacent to the downstream measurement point and the time-series data at the downstream measurement point, a weight coefficient of a linear regression equation in which an objective variable is the time-series data at the downstream measurement point, an explanatory variable is the time-series data at each of upstream measurement points adjacent to the downstream measurement point, and the weight coefficient is for a relationship between the downstream measurement point and each of the upstream measurement points adjacent to the downstream measurement point; and
estimating, from the time-series data at each of the upstream measurement points adjacent to the downstream measurement point, based on the linear regression equation using the learned weight coefficient, time-series data at the downstream measurement point.

15. The computer-readable non-transitory recording medium according to claim 6, wherein the setting data includes movement speed information.

16. The analysis method according to claim 10, the method further comprising:
outputting, as an analysis result, at least one of an explanatory text of the factor, a graph capable of visually grasping the difference, and setting data used for a simulation for measurement data at each measurement point.

17. The analysis method according to claim 10, the method further comprising:
learning, for each of downstream measurement points, based on the time-series data at each of upstream measurement points adjacent to the downstream measurement point and the time-series data at the downstream measurement point, a weight coefficient of a linear regression equation in which an objective variable is the time-series data at the downstream measurement point, an explanatory variable is the time-series data at each of upstream measurement points adjacent to the downstream measurement point, and the weight coefficient is for a relationship between the downstream measurement point and each of the upstream measurement points adjacent to the downstream measurement point; and
estimating, from the time-series data at each of the upstream measurement points adjacent to the downstream measurement point, based on the linear regression equation using the learned weight coefficient, time-series data at the downstream measurement point.

18. The computer-readable non-transitory recording medium according to claim 13, the computer-executable program instructions when executed further causing the computer system to execute the method comprising:
outputting, as an analysis result, at least one of an explanatory text of the factor, a graph capable of visually grasping the difference, and setting data used for a simulation for measurement data at each measurement point.

19. The analysis method according to claim 16, the method further comprising:
learning, for each of downstream measurement points, based on the time-series data at each of upstream measurement points adjacent to the downstream measurement point and the time-series data at the downstream measurement point, a weight coefficient of a linear regression equation in which an objective variable is the time-series data at the downstream measurement point, an explanatory variable is the time-series data at each of upstream measurement points adjacent to the downstream measurement point, and the weight coefficient is for a relationship between the downstream measurement point and each of the upstream measurement points adjacent to the downstream measurement point; and
estimating, from the time-series data at each of the upstream measurement points adjacent to the downstream measurement point, based on the linear regression equation using the learned weight coefficient, time-series data at the downstream measurement point.

20. The computer-readable non-transitory recording medium according to claim 18, the computer-executable program instructions when executed further causing the computer system to execute the method comprising:
learning, for each of downstream measurement points, based on the time-series data at each of upstream measurement points adjacent to the downstream measurement point and the time-series data at the downstream measurement point, a weight coefficient of a linear regression equation in which an objective variable is the time-series data at the downstream measurement point, an explanatory variable is the time-series data at each of upstream measurement points adjacent to the downstream measurement point, and the weight coefficient is for a relationship between the downstream measurement point and each of the upstream measurement points adjacent to the downstream measurement point; and
estimating, from the time-series data at each of the upstream measurement points adjacent to the downstream measurement point, based on the linear regression equation using the learned weight coefficient, time-series data at the downstream measurement point.
